(19) United States
(12) Patent Application Publication
(10) Pub. No.: US 2015/0003022 A1
(43) Pub. Date: Jan. 1, 2015

(54) ELECTRONIC DEVICE HAVING DISPLAY MODULE

(71) Applicant: HON HAI PRECISION INDUSTRY CO., LTD., New Taipei (TW)

(72) Inventor: Jen-Tsorng CHANG, New Taipei (TW)

(73) Assignee: HON HAI PRECISION INDUSTRY CO., LTD., New Taipei (TW)

(21) Appl. No.: 14/133,477

(22) Filed: Dec. 18, 2013

(30) Foreign Application Priority Data
Jun. 28, 2013 (TW) 102123088

(51) Int. Cl. H05K 5/03; H05K 5/00

(52) U.S. Cl. CPC H05K 5/03; H05K 5/0017
USPC 361/748; 361/679.01

(57) ABSTRACT

An electronic device includes a cover glass, two supporting frames, and a display module. The cover glass includes a central portion and two curve portions extending from two opposite edges of the central portion. The central portion includes an outer surface and an inner surface opposite to the outer surface, each curve portion is curved from an edge of the central portion toward the inner surface. Each curve portion includes a first curving surface facing the same direction as the inner surface. Each supporting frame includes a fixing portion and a supporting portion connected to the fixing portion. Each fixing portion includes a second curving surface corresponding and connecting to the first curving surface. The two supporting portions are opposite to each other, and form a receiving room with the central portion. The display module is received in the receiving room.

### BACKGROUND

1. Technical Field

The present disclosure relates to electronic devices and, particularly to an electronic device having a display module.

2. Description of Related Art

Electronic devices generally include a supporting frame, a display module, a casing, and a cover glass. The supporting frame is received in the casing. The display module is fixed on the supporting frame, and faces an opening defined in the casing. The cover glass covers the opening. However, the display module should be stably fixed on the supporting frame before being received into the casing, which complicates an assembling process of the electronic device.

Therefore, it is desirable to provide an electronic device that can overcome the limitations described.

### BRIEF DESCRIPTION OF THE DRAWINGS

FIG. 1 is a schematic view of an electronic device in accordance with an exemplary embodiment.

FIG. 2 is an exploded and schematic view of the electronic device of FIG.

FIG. 3 is a cross-sectional view taken along a line III-III of FIG. 1.

### DETAILED DESCRIPTION

Embodiments of the disclosure will be described with reference to the drawings.

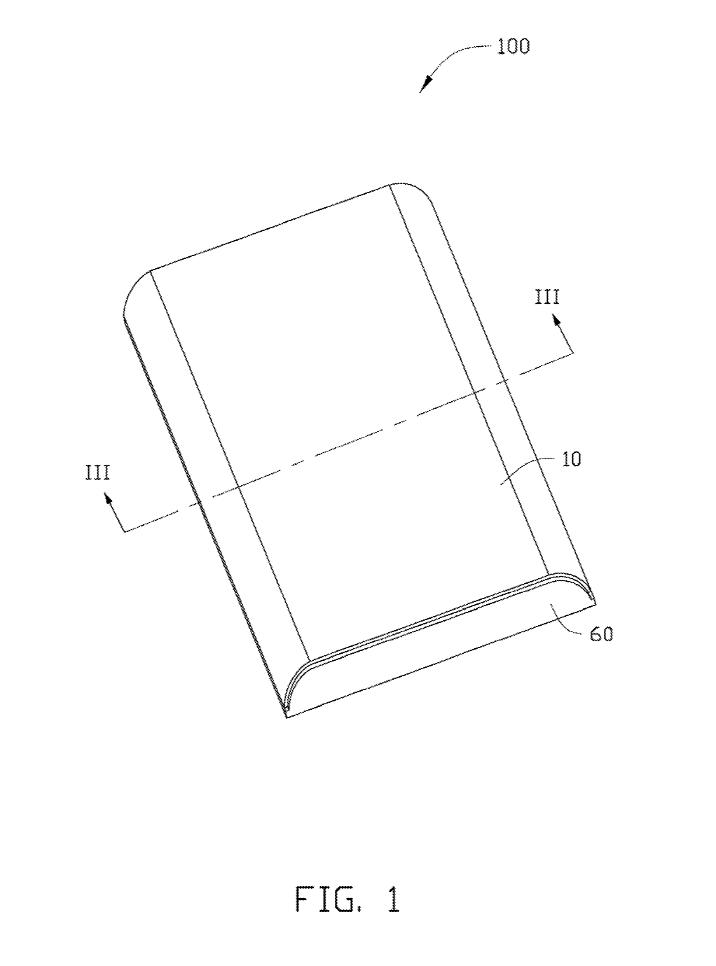

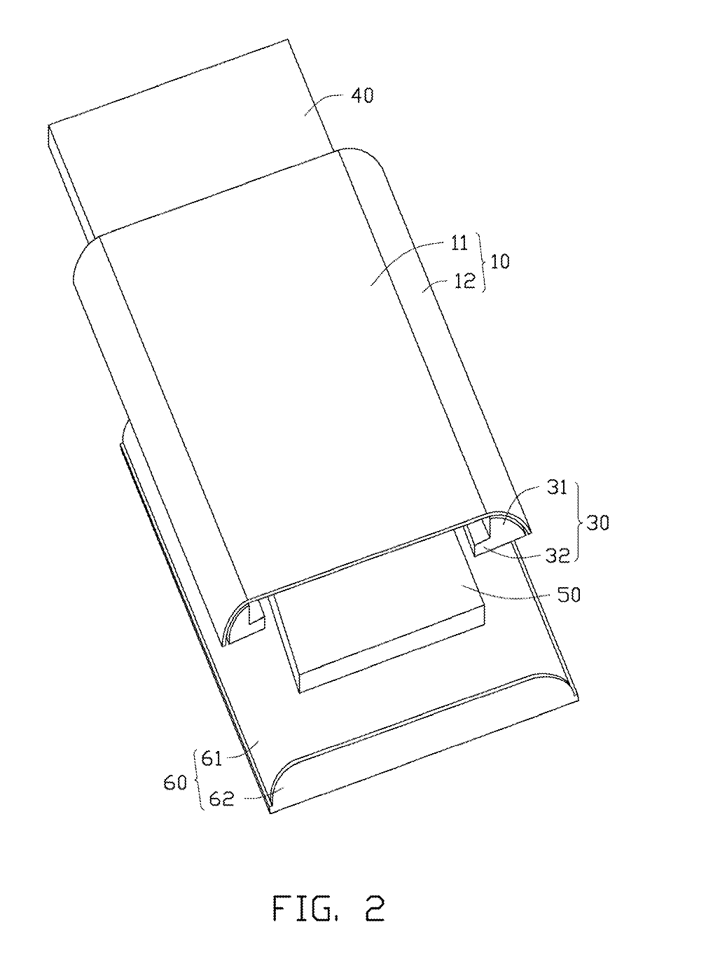

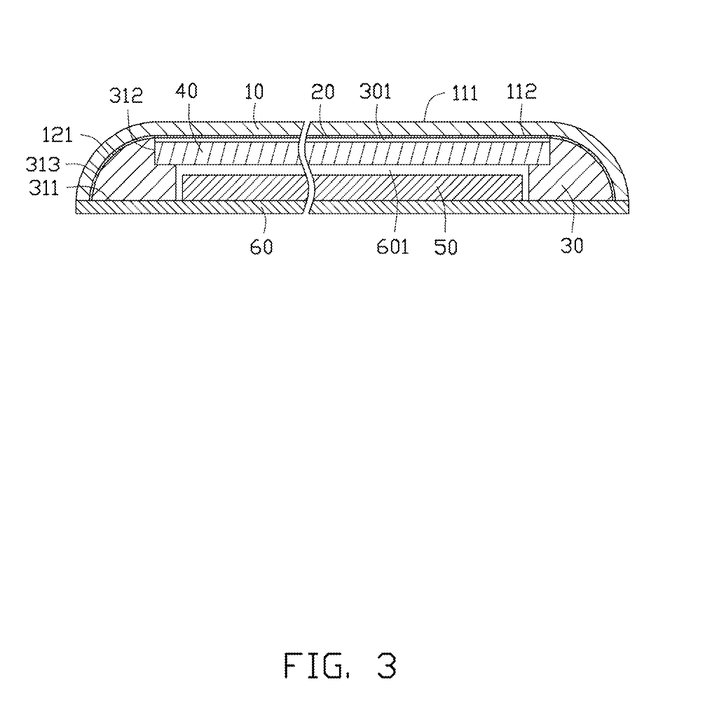

FIGS. 1-3 show an electronic device 100, according to an exemplary embodiment. The electronic device 100 includes a cover glass 10, a touch layer 20, two supporting frames 30, a display module 40, a circuit board 50, and a rear cover 60. In the embodiment, the electronic device 100 is a mobile phone.

The cover glass 10 includes a central portion 11 and two curve portions 12 extending from two opposite edges of the central portion 11. The central portion 11 is a rectangular plate, and includes an outer surface 111 facing an outer portion of the electronic device 100 and an inner surface 112 opposite to the outer surface 111. Each curve portion 12 is curved from an edge of the central portion 11 toward the inner surface 112. The curve portions 12 are formed as the two portions of the cover glass 10. The curve portions 12 are adjacent to two opposite edges and are curved respectively after being heated. Each curve portion 12 includes a first curving surface 121 facing the same direction as the inner surface 112. In the embodiment, the central portion 11 includes two opposite long sides and two opposite short sides. The curve portions 12 are connected with the two long sides of the central portion 11. In order to shield light rays, a shading ink is sprayed on the first curving surface 121.

The touch layer 20 is attached on the inner surface 112 of the central portion 11. The touch layer 20 is a capacitive touch layer. It should be understood that the touch layer 20 can be other kinds of touch layers, such as, resistive touch layer. When a user touches an outer surface 111 of the central portion 11 of the cover glass 10, a capacitance of a point of the touch layer 20 corresponding to that point of the outer surface 111 is changed, and a frequency of an oscillator connected to the touch layer 20 is changed, a touch position of the user can be decided by detecting a frequency variation.

Each supporting frame 30 is strip shaped, and is made of plastic or elastic material. The supporting frame 30 includes a fixing portion 31 and a supporting portion 32. The fixing portion 31 includes a bottom surface 311, a side surface 312 perpendicular to the bottom surface 311, and a second curving surface 313 connected between the bottom surface 311 and the side surface 312. The second curving surface 313 is corresponding to the first curving surface 121. The supporting portion 32 is positioned on the side surface 312 of the fixing portion 31, and a side of the supporting portion 32 is coplanar with the bottom surface 311.

The two supporting frames 30 are covered by the cover glass 10. The second curving surface 313 of each supporting frame 30 connects with the first curving surface 121 of the cover glass 10. Each supporting frames 30 is half-surrounded by the curve portions 12. The bottom surface 311 of the supporting frame 30 is opposite to the outer surface 111 of the cover glass 10. The two supporting frames 30 are parallel with each other, and two supporting portions 32 face each other. A receiving room 301 is formed between the supporting portions 32 and the central portion 11. In the embodiment, the first curving surface 121 is adhered with the second curving surface 313 via glue (not shown).

The display module 40 is received in the receiving room 301, and is configured for displaying images. A width of the display module 40 is equal to a vertical distance between the two side surfaces 312, therefore the display module 40 can be securely assembled between the two supporting frames 30. In the embodiment, a length of the display module 40 is equal to a length of the central portion 11 along the long side. It should be understood that the display module 40 includes a liquid crystal layer and a black light module.

The circuit board 50 is received between the two supporting portions 32, and is under the display module 40. The circuit board 50 is electrically connected to the touch layer 20 and the display module 40.

The rear cover 60 covers the cover glass 10, and forms a hermetic room 601. The touch layer 20, the supporting frames 30, the display module 40, and the circuit board 50 are received in the hermetic room 601. The rear cover 60 includes a covering portion 61 and two closing plates 62 perpendicularly positioned two opposite edges of the covering portion 61. The two closing plates 62 are positioned on the same side of the covering portion 61. The two curve portions 12 contact the covering portion 61, a side of the curve portions 12 opposite to the central portion 11 is closed by the covering portion 61. The two closing plates 62 close the two ends of the cover glass 10.

In assembly, first, the supporting frames 30 are fixed on the cover glass 10. As the receiving room 301 is being formed between the supporting frames 30 and the central portion 11 is not yet closed, the display module 40 can be assembled into the receiving room 301 from any end of the cover glass 10. Then, the circuit board 50 is assembled between the two supporting frames 30. At last, the rear cover 60 covers the cover glass 10.

In use, when a user touches the outer surface 111 of the cover glass 10. The touch layer 20 outputs a sensing signal to the circuit board 50 when detecting a touch. The circuit board 50 controls the display module 40 to display different images according to the sensing signal.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. An electronic device, comprising:
a cover glass comprising a central portion and two curve portions extending from two opposite edges of the central portion, the central portion comprising an outer surface and an inner surface opposite to the outer surface, each curve portion being curved from an edge of the central portion toward the inner surface, each curve portion comprising a first curving surface facing the same direction as the inner surface;
two supporting frames, each supporting frame comprising a fixing portion and a supporting portion extending from a side of the fixing portion, each fixing portion comprising a second curving surface corresponding to the first curving surface, the second curving surface connecting to the first curving surface; the two supporting portions being opposite to each other, and forming a receiving room with the central portion; and
a display module received in the receiving room.

2. The electronic device of claim 1, wherein each fixing portion further comprises a bottom surface and a side surface perpendicular to the bottom surface, the second curving surface is connected between the side surface and the bottom surface; the bottom surface is opposite to the outer surface, the supporting portion is positioned on the side surface.

3. The electronic device of claim 2, wherein the supporting portion is coplanar with the bottom surface of the fixing portion.

4. The electronic device of claim 1, wherein the supporting frames are half-surrounded by the curve portions respectively.

5. The electronic device of claim 1, further comprising a touch layer attached on the inner surface of the central portion.

6. The electronic device of claim 1, further comprising a circuit board received between the two supporting portions.

7. The electronic device of claim 1, further comprising a rear cover covered on the cover glass to form a hermetic room, wherein the supporting frames and the display module are received in the hermetic room.

8. The electronic device of claim 7, wherein the rear cover comprises a covering portion and two closing plates perpendicular positioned two opposite edges of the covering portion; the two curve portions contact with the covering portion, a side of the curve portions opposite to the central portion is closed by the covering portion; the two closing plates close the two ends of the cover glass.
